(19) United States
(12) Patent Application Publication
(10) Pub. No.: US 2025/0258197 A1
(43) Pub. Date: Aug. 14, 2025

(54) GUIDE PLATE AND PIN BLOCK COMPRISING THE SAME

(71) Applicant: POINT ENGINEERING CO., LTD., Asan-si (KR)

(72) Inventors: Bum Mo AHN, Suwon-si (KR); Seung Ho PARK, Hwaseong-si (KR); Tae Hwan SONG, Yongin-si (KR)

(73) Assignee: POINT ENGINEERING CO., LTD., Asan-si (KR)

(21) Appl. No.: 19/048,688

(22) Filed: Feb. 7, 2025

(30) Foreign Application Priority Data
Feb. 8, 2024 (KR) 10-2024-0019527

(51) Int. Cl. G01R 1/073; G01R 1/04

(52) U.S. Cl. CPC G01R 1/07342; G01R 1/0441

(57) ABSTRACT

The present invention provides a guide plate with an anodized film and a pin block having the same, by directly using the metal substrate, which was used to form the anodized films, as the structural material for the guide plate, thereby having anodized films on both the upper and lower portions of the metal substrate, which compensates for the vulnerability of the anodized film material.

### CROSS-REFERENCE TO RELATED APPLICATIONS

The present application claims priority to Korean Patent Application No. 10-2024-0019527, filed Feb. 8, 2024, the entire contents of which is incorporated herein for all purposes by this reference.

### TECHNICAL FIELD

The present invention relates to a guide plate into which electrically conductive pins are inserted and installed, and a pin block comprising the same.

### BACKGROUND

Inspection targets such as semiconductor devices or display panels undergo predetermined defect inspections to determine their defectiveness. For this purpose, the inspection target can be judged for defects by electrical signals from the inspection device while being electrically connected to the inspection device. The inspection of the inspection target involves electrically connecting the inspection target to the inspection device that applies the inspection signals. The inspection device and the inspection target are not directly connected to each other but are indirectly connected through electrically conductive pins provided in a guide plate. The electrically conductive pins serve as a medium connecting the terminals of the inspection target and the inspection device.

The electrical characteristic test of semiconductor devices using electrically conductive pins is divided into probe card technology for inspecting semiconductor wafers and test socket technology for inspecting semiconductor packages. Probe cards are classified into vertical probe cards, cantilever probe cards, and MEMS probe cards according to the structure of the electrically conductive pins. Test sockets include pogo type sockets, rubber type sockets, and MEMS type sockets according to the structure of the electrically conductive pins.

FIG. 1 is a schematic diagram showing a vertical probe card 1 according to the prior art.

The inspection of semiconductor chips at the wafer level is performed by a probe card. The probe card is mounted between the wafer W and the test equipment head, and 8,000 to 100,000 electrically conductive pins on the probe card contact the pads within individual chips on the wafer W, serving as an intermediate medium to exchange signals between the probe equipment and the individual chips.

Generally, the vertical probe card 1 comprises a circuit board 2, a space transformer 3 provided below the circuit board 2, and a probe head 7 provided below the space transformer 3.

The probe head 7 includes a guide plate 6, 7 having a plurality of electrically conductive pins 7 and guide holes into which the electrically conductive pins 7 are inserted. The probe head 7 includes an upper guide plate 5 and a lower guide plate 6, and the upper guide plate 5 and the lower guide plate 6 are fixedly installed through spacers. The electrically conductive pins 7 are structured to elastically deform between the upper guide plate 5 and the lower guide plate 6, and the vertical probe card 1 is configured by adopting such electrically conductive pins 7.

Just as the vertical probe card 1 requires guide plates 6, 7 for installing electrically conductive pins 7, rubber type sockets and MEMS type sockets among test sockets also require guide plates for installing electrically conductive pins.

Meanwhile, anodized films have low thermal deformation at high temperatures and possess electrical insulation properties. Research is being conducted to utilize these physical and/or electrical properties in various fields. For example, the applicant has filed applications for guide plates using anodized films (Korean Patent Publication No. 10-2021-0131691, Korean Patent Publication No. 10-2020-0104061, Korean Patent Publication No. 10-2020-0048271). The prior art supports electrically conductive pins using anodized films as the main structural material by removing the metal substrate after anodizing the metal substrate. This prior art cannot utilize the physical and/or electrical properties of the metal substrate because the metal substrate is removed.

On the other hand, it can be considered to use a metal substrate with an insulating layer deposited (ALD, CVD, PVD) as a guide plate. However, this technology may cause the metal substrate to bend in one direction during the deposition process, and it requires separate deposition equipment. Additionally, there is a problem that the deposited insulating layer may peel off from the metal substrate at its interface.

### PRIOR ART DOCUMENTS

### Patent Documents

(Patent Document 1) Korean Patent Publication No. 10-2021-0131691
(Patent Document 2) Korean Patent Publication No. 10-2020-0104061
(Patent Document 3) Korean Patent Publication No. 10-2020-0048271

### SUMMARY

The present invention aims to provide a guide plate with an anodized film applied to it, which compensates for the material's fragility by using the metal substrate employed in forming the anodized film as the structural material of the guide plate, and a pin block comprising the same.

In order to achieve the above-mentioned objectives, the guide plate according to the present invention comprises a guide plate in which guide holes into which electrically conductive pins are inserted are formed, a metal substrate, an upper anodized film integrally formed with the metal substrate and located on an upper portion of the metal substrate, and a lower anodized film integrally formed with the metal substrate and located on a lower portion of the metal substrate.

Additionally, the upper anodized film and the lower anodized film are formed by anodizing the metal substrate.

Furthermore, with respect to one guide hole, an opening area formed in the upper anodized film and an opening area formed in the lower anodized film are different.

Moreover, a concave portion is formed on a side surface of the metal substrate forming the guide hole.

Additionally, the guide hole comprises a first portion formed by the upper anodized film, a second portion formed by the metal substrate, and a third portion formed by the lower anodized film.

Furthermore, the guide hole is configured such that the first portion and the third portion are provided in a vertical shape, and the second portion is provided in a shape recessed inward.

Additionally, the guide plate further comprises a vertical guide hole in which an opening area formed in the upper anodized film, an opening area formed in the metal substrate, and an opening area formed in the lower anodized film are the same.

Moreover, a side anodized film is formed on a side surface of the metal substrate forming the guide hole so that a surface of the metal substrate is not exposed toward the guide hole.

Additionally, a plurality of the guide plates are bonded and stacked by a bonding layer in an upper and lower direction.

Furthermore, a plurality of the guide plates are fixed to each other by a fixing member at a side portion in an upper and lower direction and are spaced apart from each other at a central portion in the upper and lower direction.

Meanwhile, the pin block according to the present invention comprises an upper guide plate in which upper guide holes into which electrically conductive pins are inserted are formed, a lower guide plate in which lower guide holes into which the electrically conductive pins are inserted are formed, and a spacer provided between the upper guide plate and the lower guide plate, wherein at least one of the upper guide plate and the lower guide plate comprises a metal substrate, an upper anodized film integrally formed with the metal substrate and located on an upper portion of the metal substrate, and a lower anodized film integrally formed with the metal substrate and located on a lower portion of the metal substrate.

Additionally, the upper guide hole in which a head portion of the electrically conductive pin is located has a structure in which an upper side opening area is smaller than a lower side opening area, and the lower guide hole in which a tail portion of the electrically conductive pin is located has a structure in which an upper side opening area is larger than a lower side opening area.

Furthermore, the upper guide plate comprises a first upper guide plate and a second upper guide plate, the first upper guide plate and the second upper guide plate are fixed to each other by an upper fixing member at a side portion in an upper and lower direction and are spaced apart from each other at a central portion in the upper and lower direction, and a lower anodized film of the first upper guide plate and an upper anodized film of the second upper guide plate face each other.

Additionally, the lower guide plate comprises a first lower guide plate and a second lower guide plate, the first lower guide plate and the second lower guide plate are fixed to each other by a lower fixing member at a side portion in an upper and lower direction and are spaced apart from each other at a central portion in the upper and lower direction, and a lower anodized film of the first lower guide plate and an upper anodized film of the second upper guide plate face each other.

Furthermore, the upper guide plate comprises a first upper guide plate and a second upper guide plate, the first upper guide plate and the second upper guide plate are bonded and stacked by a bonding layer in an upper and lower direction, and a first lower anodized film of the first upper guide plate and a second upper anodized film of the second upper guide plate face each other.

Additionally, the lower guide plate comprises a first lower guide plate and a second lower guide plate, the first lower guide plate and the second lower guide plate are bonded and stacked by a bonding layer in an upper and lower direction, and a lower anodized film of the first lower guide plate and an upper anodized film of the second lower guide plate face each other.

The present invention provides a guide plate with an anodized film applied, which compensates for the material's fragility by using the metal substrate used in forming the anodized film as the structural material of the guide plate, and a pin block comprising the same.

### BRIEF DESCRIPTION OF DRAWINGS

The above and other features of embodiments of the disclosure will become apparent by describing in detail embodiments thereof with reference to the accompanying drawings.

FIG. 1 is a view showing a probe card according to the prior art.

FIG. 2 is a view showing a pin block without electrically conductive pins according to a preferred first embodiment of the present invention.

FIG. 3 is a view showing a guide plate according to a preferred first embodiment of the present invention.

FIG. 4 is a view showing a pin block with electrically conductive pins according to a preferred first embodiment of the present invention.

FIGS. 5 to 10 are views explaining the manufacturing method of the guide plate according to a preferred first embodiment of the present invention.

FIGS. 11 to 14 are views showing modifications of the pin block according to a preferred first embodiment of the present invention.

FIG. 15 is a view showing a pin block without electrically conductive pins according to a preferred second embodiment of the present invention.

FIG. 16 is a view showing a guide plate according to a preferred second embodiment of the present invention.

FIG. 17 is a view showing a pin block with electrically conductive pins according to a preferred second embodiment of the present invention.

FIGS. 18 to 20 are views explaining the manufacturing method of the guide plate according to a preferred second embodiment of the present invention.

FIGS. 21 and 22 are views showing modifications of the pin block according to a preferred second embodiment of the present invention.

FIG. 23 is a view showing a pin block without electrically conductive pins according to a preferred third embodiment of the present invention.

FIG. 24 is a view showing a guide plate according to a preferred third embodiment of the present invention.

FIG. 25 is a view showing a pin block with electrically conductive pins according to a preferred third embodiment of the present invention.

FIG. 26 is a plan view of the pin block according to a preferred third embodiment of the present invention.

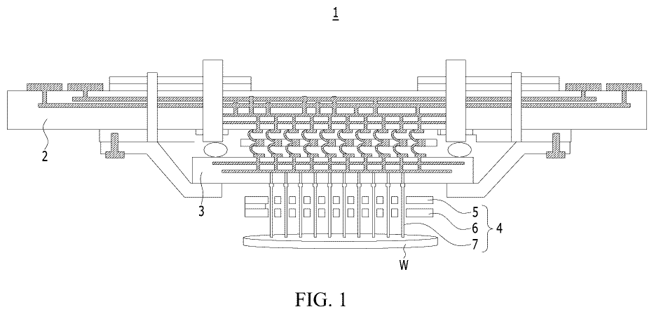

### DETAILED DESCRIPTION OF THE EMBODIMENTS

The following content merely illustrates the principles of the invention. Therefore, those skilled in the art can devise various devices that embody the principles of the invention and are included within the concept and scope of the invention, even if they are not explicitly described or illustrated in this specification. Additionally, all conditional terms and embodiments listed in this specification are intended, in principle, solely to aid in understanding the concept of the invention and should not be understood as limiting the specifically listed embodiments and conditions.

The above-mentioned objectives, features, and advantages will become more apparent through the following detailed description in conjunction with the accompanying drawings, thereby enabling those skilled in the art to easily implement the technical idea of the invention.

The embodiments described in this specification will be explained with reference to ideal exemplary cross-sectional and/or perspective views of the invention. The thicknesses of films and regions shown in these drawings are exaggerated for effective explanation of the technical content. The shapes in the exemplary drawings may be modified due to manufacturing techniques and/or tolerances. Therefore, the embodiments of the invention are not limited to the specific forms shown but also include changes in form generated by the manufacturing process. The technical terms used in this specification are merely used to describe specific embodiments and are not intended to limit the invention. Singular expressions include plural expressions unless the context clearly indicates otherwise. In this specification, terms such as “comprising” or “including” are intended to specify the presence of features, numbers, steps, operations, components, parts, or combinations thereof described in this specification, and do not preclude the possibility of the presence or addition of one or more other features, numbers, steps, operations, components, parts, or combinations thereof.

The core idea of the solution underlying the present invention is to adopt a guide plate with anodized films formed on the upper and lower portions of a metal substrate, utilizing the metal substrate used to form the upper and lower anodized films as a structural material without removing it, thereby overcoming the material's vulnerability.

The guide plate described below is provided in an inspection device and used to support electrically conductive pins. The inspection device may be an inspection device used in semiconductor manufacturing processes or display manufacturing processes. The inspection device may be, for example, a probe card or an inspection device including a test socket. The inspection device includes electrically conductive pins and a guide plate having guide holes for accommodating the electrically conductive pins. The electrically conductive pins may be probe pins provided in a probe card or socket pins provided in a test socket.

Hereinafter, preferred embodiments of the present invention will be described in detail with reference to the accompanying drawings. In describing various embodiments below, components performing the same function will be given the same names and reference numbers for convenience, even if the embodiments are different. Additionally, the configuration and operation already described in other embodiments will be omitted for convenience.

### First Embodiment

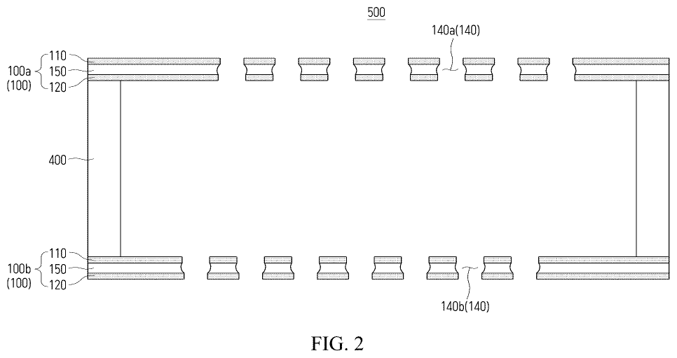

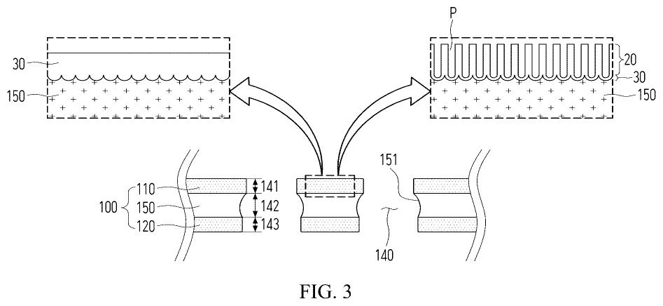

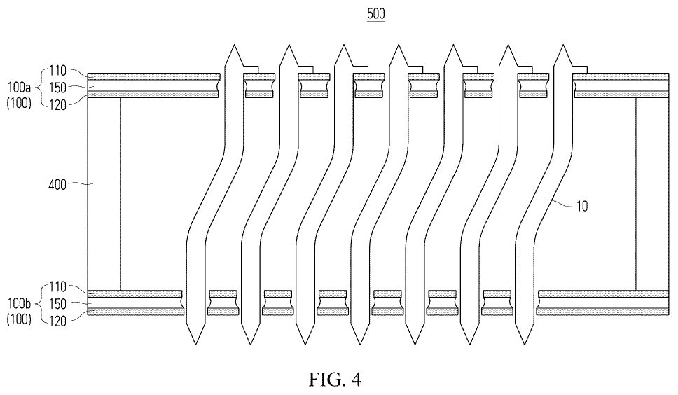

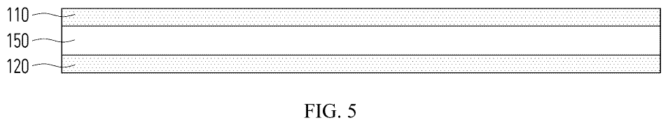

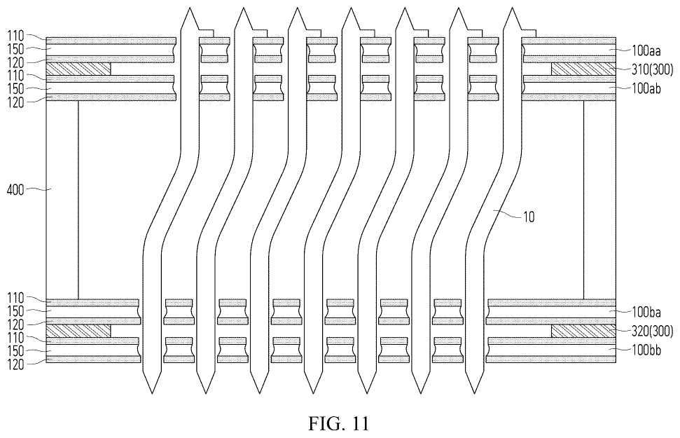

FIG. 2 is a view showing a pin block 500 without electrically conductive pins 10 according to a preferred first embodiment of the present invention, FIG. 3 is a view showing a guide plate 100 according to a preferred first embodiment of the present invention, FIG. 4 is a view showing a pin block 500 with electrically conductive pins 10 according to a preferred first embodiment of the present invention, FIGS. 5 to 10 are views explaining the manufacturing method of the guide plate 100 according to a preferred first embodiment of the present invention, and FIGS. 11 to 14 are views showing other embodiments of the pin block 500 according to a preferred first embodiment of the present invention. Hereinafter, the upper side means the upper side based on the drawings, and the lower side means the lower side based on the drawings.

Referring to FIGS. 2 to 4, the pin block 500 includes a guide plate 100 in which guide holes 140 for inserting electrically conductive pins 10 are formed. The guide plate 100 includes an upper guide plate 100a in which upper guide holes 140a are formed and a lower guide plate 100b in which lower guide holes 140b are formed. A spacer 400 is provided between the upper guide plate 100a and the lower guide plate 100b.

At least one of the upper guide plate 100a and the lower guide plate 100b includes a metal substrate 150, an upper anodized film 110 integrally formed with the metal substrate 150 and located on the upper portion of the metal substrate 150, and a lower anodized film 120 integrally formed with the metal substrate 150 and located on the lower portion of the metal substrate 150. The guide plate 100 compensates for the vulnerability of the upper anodized film 110 and the lower anodized film 120 by having the metal substrate 150, which functions as a structural material, inside.

The upper anodized film 110 and the lower anodized film 120 are films formed by anodizing the metal substrate 150. When the metal substrate 150 is aluminum (Al) or an aluminum alloy, anodizing the metal substrate 150 forms upper anodized film 110 and lower anodized film 120 made of aluminum oxide (Al₂O₃) on both surfaces of the metal substrate 150. The metal substrate 150 includes any metal material that can be anodized. For example, the metal substrate 150 may include tantalum (Ta), niobium (Nb), titanium (Ti), zirconium (Zr), hafnium (Hf), tungsten (W), antimony (Sb), or alloys thereof, but is not limited thereto.

The upper anodized film 110 and the lower anodized film 120 may have a structure including a porous layer 20 having pores P formed during anodizing and a barrier layer 30 located between the porous layer 20 and the metal substrate 150 (refer to the upper right of FIG. 3) or a structure including only the barrier layer 30 (refer to the upper left of FIG. 3). Here, the porous layer 20 and the barrier layer 30 are films formed on the surface of the metal substrate 150 when the metal substrate 150 is anodized.

During the process of installing electrically conductive pins 10 in the guide plate 100 and performing overdrive, the electrically conductive pins 10 apply shear force to the guide holes 140. Since the upper anodized film 110 and the lower anodized film 120 are films formed by anodizing the metal substrate 150, they are more robustly integrated with the metal substrate 150 compared to films formed through deposition processes (CVD, PVD, ALD). Therefore, even if the electrically conductive pins 10 apply shear force to the upper anodized film 110 or the lower anodized film 120, the upper anodized film 110 or the lower anodized film 120 does not easily peel off from the metal substrate 150.

The upper anodized film 110 and the lower anodized film 120 have a thermal expansion coefficient of 2-3 ppm/° C. As a result, they exhibit minimal thermal deformation when exposed to high-temperature environments. Additionally, since the thermal expansion coefficient of the upper anodized film 110 and the lower anodized film 120 is close to that of a semiconductor wafer, the positional accuracy of the electrically conductive pins 10 can be maintained during the inspection process.

Furthermore, the upper anodized film 110 and the lower anodized film 120 can resist the relatively large thermal expansion of the metal substrate 150 in high-temperature environments, thereby maintaining the positional accuracy of the electrically conductive pins 10 despite temperature changes. In particular, since the metal substrate 150 is not exposed to the outside due to the upper anodized film 110 and the lower anodized film 120, the thermal expansion of the metal substrate 150 can be minimized even in high-temperature environments. Therefore, the guide plate 100 can be used without thermal deformation even in high-temperature environments such as burn-in tests.

The guide plate 100 has a structure in which the upper anodized film 110 and the lower anodized film 120 are symmetrically provided on the upper and lower portions of the metal substrate 150. As a result, the guide plate 100 can prevent bending in any one direction.

Also, the guide plate 100 can facilitate heat dissipation and heat transfer to the outside in a high-temperature environment by utilizing the high thermal conductivity of the metal substrate 150. Specifically, since the metal substrate 150 is exposed to the outside from the side of the guide hole 140, it can absorb surrounding heat and disperse it internally or dissipate internal heat to the outside.

The opening area formed in the upper anodized film 110 and the opening area formed in the lower anodized film 120 may differ with respect to one guide hole 140. When the opening area formed in the upper anodized film 110 and the opening area formed in the lower anodized film 120 are different, one opening area is larger or smaller than the other.

A concave portion 151 is formed on the side surface of the metal substrate 150 forming the guide hole 140. The concave portion 151 is provided in a shape recessed inward in the direction of the metal substrate 150.

The guide hole 140 comprises a first portion 141 formed by the upper anodized film 110, a second portion 142 formed by the metal substrate 150, and a third portion 143 formed by the lower anodized film 120. The first portion 141, the second portion 142, and the third portion 143 are terms used to distinguish the positions of the guide hole 140. The first portion 141 of the guide hole 140 refers to the hole located in the upper anodized film 110, the second portion 142 of the guide hole 140 refers to the hole located in the metal substrate 150, and the third portion 143 of the guide hole 140 refers to the hole located in the lower anodized film 120.

The first portion 141 and the third portion 143 of the guide hole 140 are provided in a vertical shape, and the second portion 142 is provided in a shape recessed inward, continuous with the first portion 141 and the third portion 143. As the second portion 142 is provided in a recessed shape relative to the first portion 141 and the third portion 143, the electrically conductive pin 10 does not contact the metal substrate 150, thereby preventing the electrically conductive pin 10 from being electrically connected to the guide plate 100.

Meanwhile, to further ensure insulation between the electrically conductive pin 10 and the guide plate 100, an additional insulating coating layer (not shown) may be provided on the inner wall surface of the guide hole 140.

The opening area of the first portion 141 and the opening area of the third portion 143 may differ. For example, referring to FIG. 3, the opening area of the first portion 141 is smaller than the opening area of the third portion 143. However, this is not limited thereto, and as described below, the guide plate 100 may be used in a reversed state, in which case the opening area of the first portion 141 is larger than the opening area of the third portion 143.

When the guide hole 140 is configured only in a vertical shape, the inner wall surface of the guide hole 140 and the outer surface of the electrically conductive pin 10 contact each other overall, increasing frictional resistance. However, according to this embodiment, since the electrically conductive pin 10 is likely to contact only the inner wall surface of the first portion 141 and not the inner wall surfaces of the second portion 142 and the third portion 143, the frictional resistance is relatively low, facilitating the vertical movement of the electrically conductive pin 10 within the guide hole 140.

Referring to FIGS. 2 and 4, the upper guide hole 140a, where the head of the electrically conductive pin 10 is located, has a structure in which the upper side opening area is smaller than the lower side opening area, and the lower guide hole 140b, where the tail of the electrically conductive pin 10 is located, has a structure in which the upper side opening area is larger than the lower side opening area. In other words, the upper guide hole 140a of the upper guide plate 100a has an upper side opening area smaller than the lower side opening area, and the lower guide hole 140b of the lower guide plate 100b has an upper side opening area larger than the lower side opening area.

The upper guide hole 140a has a structure in which the upper side is narrower and the lower side is wider. This supports the electrically conductive pin 10 so that it does not shake and allows the electrically conductive pin 10 to be arranged in a narrow pitch. Additionally, the lower side of the upper guide hole 140a is relatively wide, making it easier for the electrically conductive pin 10 to elastically deform.

The lower guide hole 140b has a structure in which the upper side is wider and the lower side is narrower. This supports the electrically conductive pin 10 so that it does not shake and allows the electrically conductive pin 10 to be arranged in a narrow pitch. Additionally, the upper side of the lower guide hole 140b is relatively wide, making it easier for the electrically conductive pin 10 to elastically deform.

There are methods for manufacturing a pin block 500 with the electrically conductive pin 10 inserted, including (i) inserting the electrically conductive pin 10 in the state where the upper guide plate 100a and the lower guide plate 100b are arranged as shown in FIG. 2 to complete the pin block 500 as shown in FIG. 4, and (ii) inserting the electrically conductive pin 10 in the state where the upper guide hole 140a of the upper guide plate 100a and the lower guide hole 140b of the lower guide plate 100b are aligned vertically, then shifting the upper guide plate 100a or the lower guide plate 100b to one side to complete the pin block 500 as shown in FIG. 4.

Hereinafter, a method for manufacturing the guide plate 100 according to a preferred first embodiment of the present invention will be described with reference to FIGS. 5 to 10.

First, referring to FIG. 5, the metal substrate 150 is anodized. The material of the metal substrate may include aluminum (Al), tantalum (Ta), niobium (Nb), titanium (Ti), zirconium (Zr), hafnium (Hf), tungsten (W), antimony (Sb), or alloys thereof, but is not limited thereto. By anodizing the metal substrate 150, an upper anodized film 110 is integrally formed on the upper portion of the metal substrate 150, and a lower anodized film 120 is integrally formed on the lower portion of the metal substrate 150. Since the upper anodized film 110 and the lower anodized film 120 are symmetrically formed on the upper and lower portions of the metal substrate 150, the metal substrate 150 can be prevented from bending in any one direction.

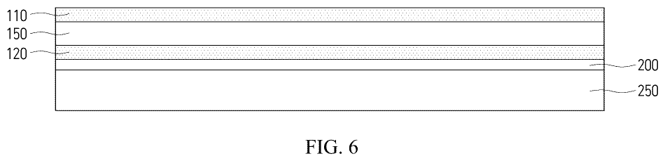

Next, referring to FIG. 6, the anodized metal substrate 150 is attached to a carrier substrate 250 using an adhesive layer 200.

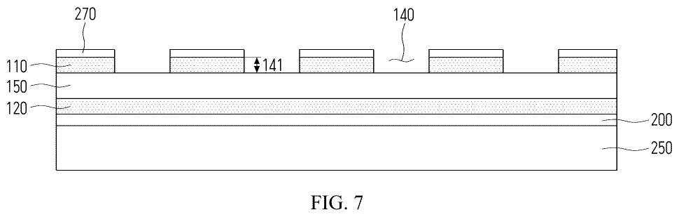

Next, referring to FIG. 7, the upper anodized film 110 is etched to form a hole corresponding to the first portion 141 of the guide hole 140. To this end, a patternable material 270, such as photoresist, is formed on the upper portion of the upper anodized film 110, and then the patternable material 270 is patterned to form an opening area. The upper anodized film 110 is etched using the opening area. More specifically, the upper anodized film 110 is removed by wet etching using a solution that reacts only with the anodized film, corresponding to the opening area. Through this, the first portion 141 of the guide hole 140 is formed. The side surface of the first portion 141 of the guide hole 140 is formed in a vertical shape.

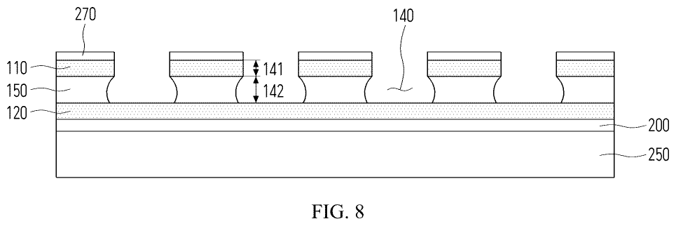

Next, referring to FIG. 8, the metal substrate 150 is etched to form a hole corresponding to the second portion 142 of the guide hole 140. To this end, the metal substrate 150 is wet-etched using a chemical solution. When the metal substrate 150 is wet-etched, the lateral width of the second portion 142 becomes larger than the lateral width of the first portion 141 due to isotropic etching action. Since the metal substrate 150 is wet-etched using the first portion 141 of the upper anodized film 110, the second portion 142 is continuously formed with the first portion 141. Meanwhile, due to the effect of unidirectional isotropic wet etching on the metal substrate, the lateral width of the lower side of the second portion 142 becomes larger than the lateral width of the upper side of the second portion 142.

Meanwhile, methods for forming holes in the metal substrate 150 may include using gas and/or plasma, using a laser, or using a chemical solution, and one of these methods or a combination thereof may be used.

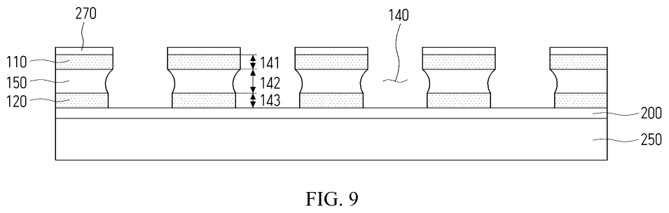

Next, referring to FIG. 9, the lower anodized film 120 is etched to form a hole corresponding to the third portion 143 of the guide hole 140. To this end, the lower anodized film 120 is wet-etched using the second portion 142 of the guide hole 140. As a result, the third portion 143 is continuously formed with the second portion 142 and its side surface is formed in a vertical shape.

Since the lateral width of the lower side of the second portion 142 is larger than the lateral width of the upper side of the second portion 142, the opening area of the third portion 143 is larger than the opening area of the first portion 141.

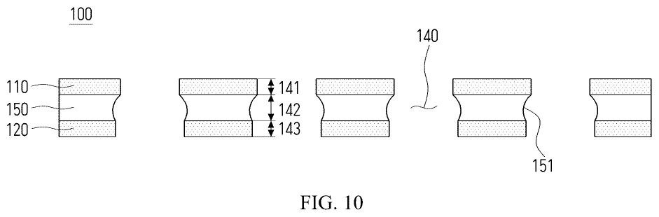

Next, referring to FIG. 10, by removing the patternable material 270, the adhesive layer 200, and the carrier substrate 250, the fabrication of the guide plate 100, which includes the upper anodized film 110 and the lower anodized film 120 on both sides of the metal substrate 150, is completed.

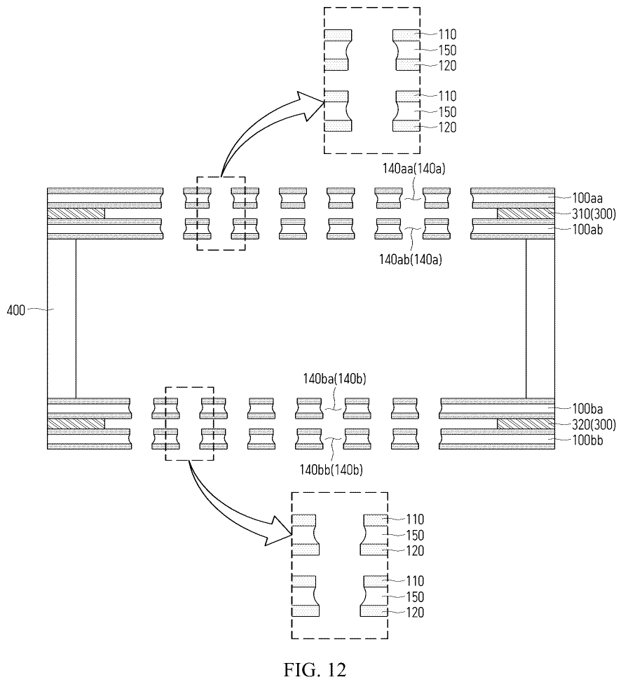

FIGS. 11 and 12 illustrate a first modification of the pin block 500 shown in FIG. 4. The first modification described below will be explained focusing on the characteristic components compared to the first embodiment described above, and the description of components that are the same or similar to those of the first embodiment will be omitted as much as possible.

A plurality of guide plates 100 may be fixed to each other by a fixing member 300 at a side portion in an upper and lower direction and may be spaced apart from each other at a central portion in the upper and lower direction.

Referring to FIGS. 11 and 12, the upper guide plate 100a includes a first upper guide plate 100aa having a first upper guide hole 140aa and a second upper guide plate 100ab having a second upper guide hole 140ab located below the first upper guide plate 100aa.

The lower guide plate 100b includes a first lower guide plate 100ba having a first lower guide hole 140ba and a second lower guide plate 100bb having a second lower guide hole 140bb located below the first lower guide plate 100ba.

The first upper guide plate 100aa and the second upper guide plate 100ab are fixed to each other by an upper fixing member 310 at a side portion in an upper and lower direction and are spaced apart from each other at a central portion in the upper and lower direction. The lower anodized film 120 of the first upper guide plate 100aa and the upper anodized film 110 of the second upper guide plate 100ab face each other.

The first lower guide plate 100ba and the second lower guide plate 100bb are fixed to each other by a lower fixing member 320 at a side portion in an upper and lower direction and are spaced apart from each other at a central portion in the upper and lower direction. The lower anodized film 120 of the first lower guide plate 100ba and the upper anodized film 110 of the second lower guide plate 100bb face each other.

The first upper guide hole 140aa of the first upper guide plate 100aa is arranged in a structure in which the upper side opening area is smaller than the lower side opening area. As a result, since the upper part of the first upper guide hole 140aa is relatively narrow, it supports the electrically conductive pin 10 inserted therein so that the electrically conductive pin 10 does not shake, and it is possible to arrange the electrically conductive pins 10 in a narrow pitch.

The second upper guide hole 140ab of the second upper guide plate 100ab is arranged in a structure in which the upper side opening area is larger than the lower side opening area. As a result, the tail portion of the electrically conductive pin 10 that has passed through the first upper guide hole 140aa is more easily guided and inserted into the second upper guide hole 140ab. On the other hand, the second upper guide hole 140ab may be arranged in a structure in which the upper side opening area is smaller than the lower side opening area, in which case, unlike what is shown in the drawing, the electrically conductive pin 10 is inserted into the second upper guide hole 140ab from below.

The first lower guide hole 140ba of the first lower guide plate 100ba is arranged in a structure in which the upper side opening area is larger than the lower side opening area. As a result, the tail portion of the electrically conductive pin 10 that has passed through the second upper guide hole 140ab is more easily guided and inserted into the first lower guide hole 140ba. On the other hand, the first lower guide hole 140ba may be arranged in a structure in which the upper side opening area is smaller than the lower side opening area, in which case, unlike what is shown in the drawing, the electrically conductive pin 10 is inserted into the first lower guide hole 140ba from below.

The second lower guide hole 140bb of the second lower guide plate 100bb is arranged in a structure in which the upper side opening area is larger than the lower side opening area. As a result, the tail portion of the electrically conductive pin 10 that has passed through the first lower guide hole 140ba is more easily guided and inserted into the second lower guide hole 140bb. Also, since the lower part of the second lower guide hole 140bb is relatively narrow, it supports the electrically conductive pin 10 so that the electrically conductive pin 10 does not shake, and it is possible to arrange the electrically conductive pins 10 in a narrow pitch.

By arranging the first upper guide hole 140aa, the second upper guide hole 140ab, the first lower guide hole 140ba, and the second lower guide hole 140bb in the order of upper narrow lower wide, upper wide lower narrow, upper wide lower narrow, and upper wide lower narrow structures, it is possible to more easily insert and install the electrically conductive pins 10, and to firmly support the electrically conductive pins 10.

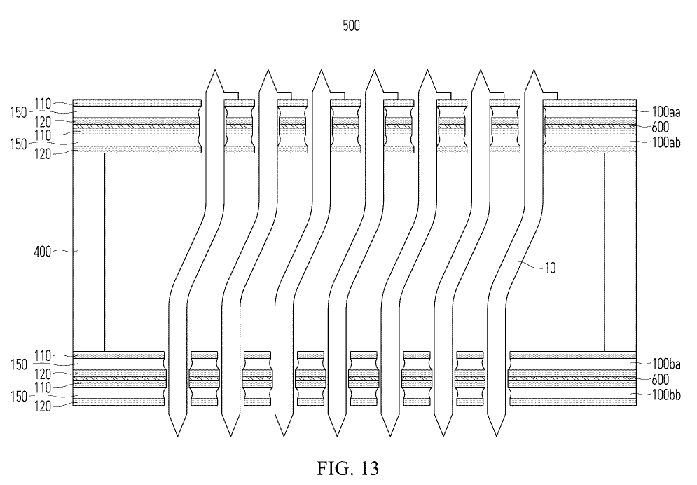

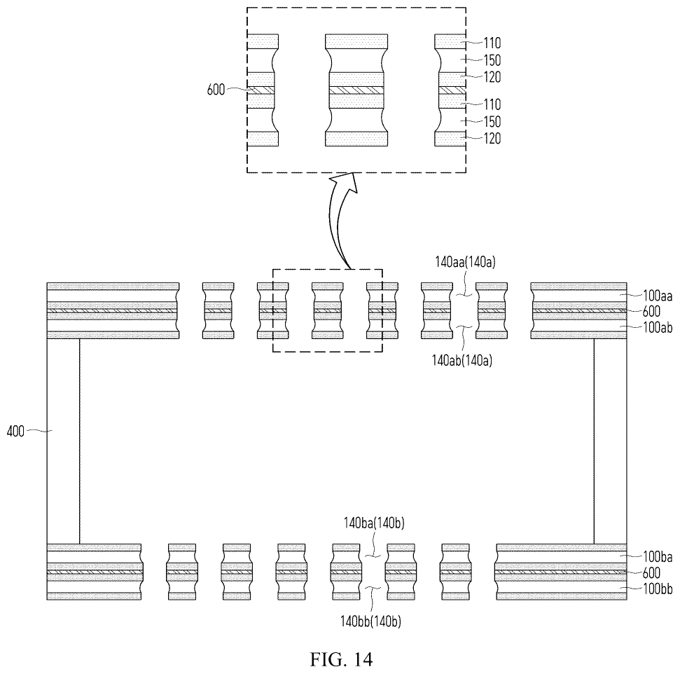

FIGS. 13 and 14 illustrate a second modification of the pin block 500 shown in FIG. 4. The second modification described below will be explained focusing on the characteristic components compared to the first embodiment described above, and the description of components that are the same or similar to those of the first embodiment will be omitted as much as possible.

A plurality of guide plates 100 may be bonded and stacked by a bonding layer 600 in an upper and lower direction.

Referring to FIGS. 13 and 14, the upper guide plate 100a includes a first upper guide plate 100aa having a first upper guide hole 140aa and a second upper guide plate 100ab having a second upper guide hole 140ab located below the first upper guide plate 100aa.

The lower guide plate 100b includes a first lower guide plate 100ba having a first lower guide hole 140ba and a second lower guide plate 100bb having a second lower guide hole 140bb located below the first lower guide plate 100ba.

The first upper guide plate 100aa and the second upper guide plate 100ab are bonded and stacked by a bonding layer 600 in an upper and lower direction. The lower anodized film 120 of the first upper guide plate 100aa and the upper anodized film 110 of the second upper guide plate 100ab face each other.

Since the first upper guide plate 100aa and the second upper guide plate 100ab are bonded to each other to form the upper guide plate 100a, it is advantageous in terms of strength compared to forming the upper guide plate 100a alone.

The first lower guide plate 100ba and the second lower guide plate 100bb are bonded and stacked by a bonding layer 600 in an upper and lower direction. The lower anodized film 120 of the first lower guide plate 100ba and the upper anodized film 110 of the second lower guide plate 100bb face each other.

Since the first lower guide plate 100ba and the second lower guide plate 100bb are bonded to each other to form the lower guide plate 100b, it is advantageous in terms of strength compared to forming the lower guide plate 100b alone.

Here, the material of the bonding layer 600 is not particularly limited, but may include a photoresist having adhesiveness.

The first upper guide hole 140aa of the first upper guide plate 100aa is arranged in a structure in which the upper side opening area is smaller than the lower side opening area. On the other hand, the second upper guide hole 140ab of the second upper guide plate 100ab is arranged in a structure in which the upper side opening area is larger than the lower side opening area. When the first upper guide plate 100aa and the second upper guide plate 100ab are bonded, they are symmetrical in the upper and lower directions based on the bonding layer 600. Accordingly, the opening areas of the entrance and exit of the upper guide hole 140a formed in the first upper guide plate 100aa and the second upper guide plate 100ab are smaller than the internal opening area. Therefore, it is possible to more firmly support the electrically conductive pin 10 at the entrance and exit of the upper guide hole 140a.

Of course, unlike what is shown in the drawing, the first upper guide hole 140aa may be arranged in a structure in which the upper side opening area is larger than the lower side opening area, and the second upper guide hole 140ab may be arranged in a structure in which the upper side opening area is smaller than the lower side opening area, so that the first upper guide plate 100aa and the second upper guide plate 100ab are symmetrical in the upper and lower directions based on the bonding layer 600 when bonded.

The first lower guide hole 140ba of the first lower guide plate 100ba is arranged in a structure in which the upper side opening area is larger than the lower side opening area. On the other hand, the second lower guide hole 140bb of the second lower guide plate 100bb is arranged in a structure in which the upper side opening area is smaller than the lower side opening area. When the first lower guide plate 100ba and the second lower guide plate 100bb are bonded, they are symmetrical in the upper and lower directions based on the bonding layer 600. Of course, the first lower guide hole 140ba may be arranged in a structure in which the upper side opening area is smaller than the lower side opening area, and the second lower guide hole 140bb may be arranged in a structure in which the upper side opening area is larger than the lower side opening area.

### Second Embodiment

Next, a second embodiment according to the present invention will be described. The second embodiment described below will be explained focusing on the characteristic components compared to the first embodiment described above, and the description of components that are the same or similar to those of the first embodiment will be omitted as much as possible.

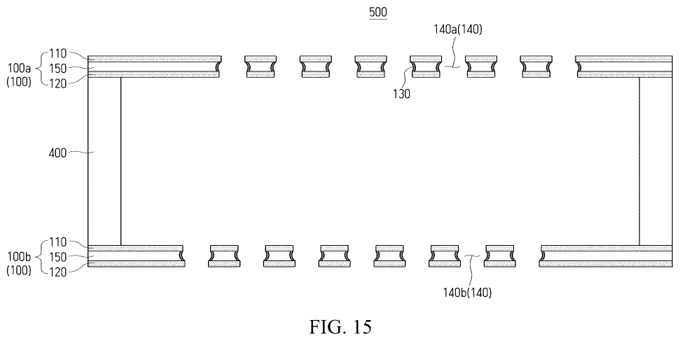

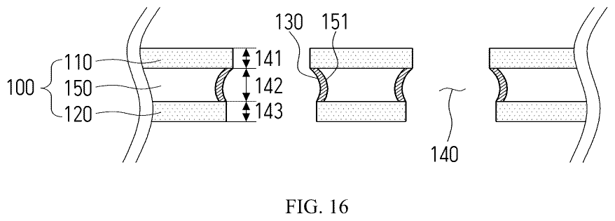

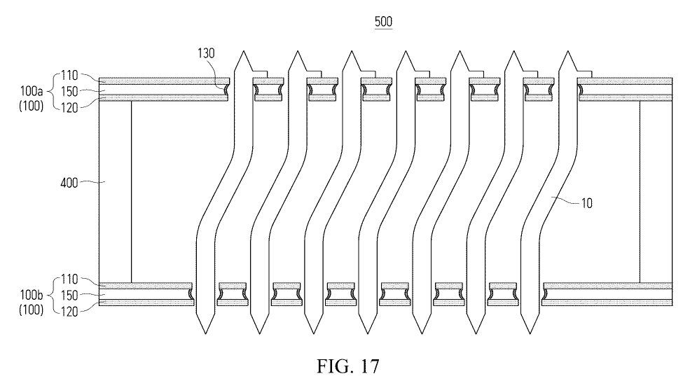

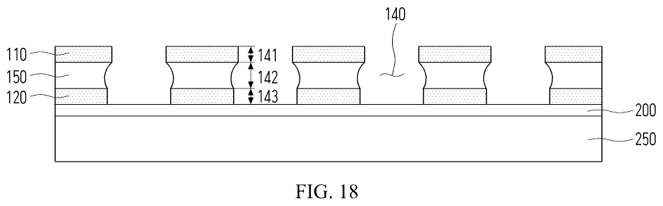

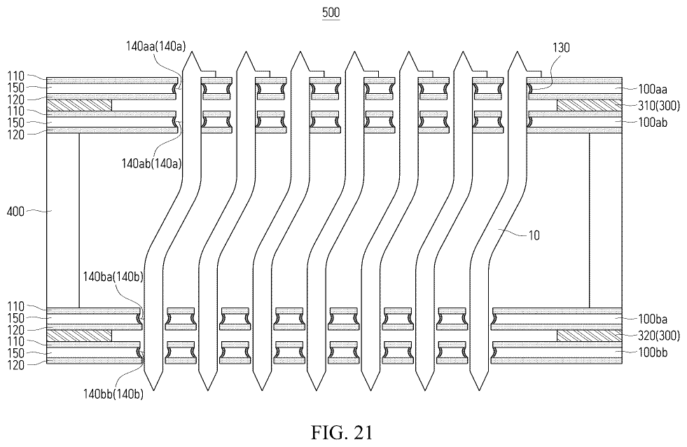

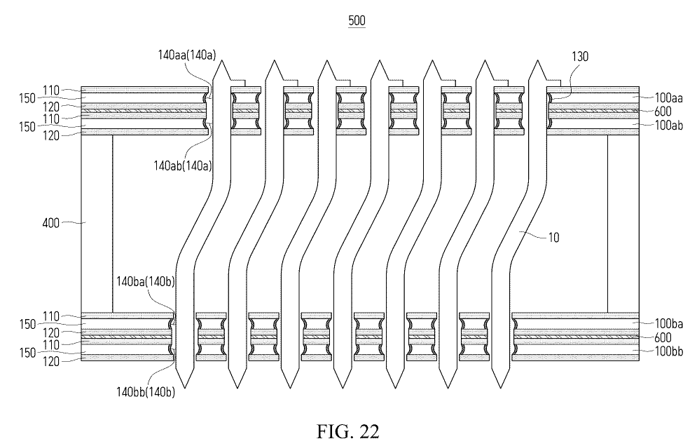

FIG. 15 is a diagram showing a pin block 500 without electrically conductive pins 10 according to a preferred second embodiment of the present invention, FIG. 16 is a diagram showing a guide plate 100 according to a preferred second embodiment of the present invention, FIG. 17 is a diagram showing a pin block 500 with electrically conductive pins 10 according to a preferred second embodiment of the present invention, FIGS. 18 to 20 are diagrams explaining a manufacturing method of the guide plate 100 according to a preferred second embodiment of the present invention, and FIGS. 21 and 22 are diagrams showing modifications of the pin block 500 according to a preferred second embodiment of the present invention.

Referring to FIGS. 15 to 17, the pin block 500 comprises a guide plate 100 in which guide holes 140 into which electrically conductive pins 10 are inserted are formed. The guide plate 100 comprises an upper guide plate 100a in which upper guide holes 140a are formed and a lower guide plate 100b in which lower guide holes 140b are formed. A spacer 400 is provided between the upper guide plate 100a and the lower guide plate 100b.

At least one of the upper guide plate 100a and the lower guide plate 100b comprises a metal substrate 150, an upper anodized film 110 integrally formed with the metal substrate 150 and located on an upper portion of the metal substrate 150, and a lower anodized film 120 integrally formed with the metal substrate 150 and located on a lower portion of the metal substrate 150.

The upper anodized film 110 and the lower anodized film 120 are films formed by anodizing the metal substrate 150. When the metal substrate 150 is aluminum (Al) or an aluminum alloy, anodizing the metal substrate 150 forms the upper anodized film 110 and the lower anodized film 120 of aluminum oxide (Al₂O₃) material on both surfaces of the metal substrate 150. However, the metal substrate 150 is not limited to this and includes tantalum (Ta), niobium (Nb), titanium (Ti), zirconium (Zr), hafnium (Hf), tungsten (W), antimony (Sb), or alloys thereof.

The upper anodized film 110 and the lower anodized film 120 have a thermal expansion coefficient of 2-3 ppm/° C. Therefore, when exposed to a high-temperature environment, thermal deformation due to temperature is minimal. Additionally, the thermal expansion coefficient of the upper anodized film 110 and the lower anodized film 120 is close to that of a semiconductor wafer, allowing the positional accuracy of the electrically conductive pins 10 to be maintained during inspection.

Furthermore, the relatively large thermal expansion of the metal substrate 150 in a high-temperature environment can be resisted by the upper anodized film 110 and the lower anodized film 120, maintaining the positional accuracy of the electrically conductive pins 10 despite temperature changes. Particularly, since the metal substrate 150 is not exposed to the outside due to the upper anodized film 110 and the lower anodized film 120, the thermal expansion of the metal substrate 150 can be minimized even in a high-temperature environment. Therefore, the guide plate 100 can be used without thermal deformation even in high-temperature environments such as burn-in tests.

The guide plate 100 has a structure in which the upper anodized film 110 and the lower anodized film 120 are symmetrically provided on the upper and lower portions of the metal substrate 150. This prevents the guide plate 100 from bending in any one direction.

With respect to one guide hole 140, the opening area formed in the upper anodized film 110 and the opening area formed in the lower anodized film 120 are not the same and differ. Since the opening areas formed in the upper anodized film 110 and the lower anodized film 120 differ, one is larger or smaller than the other.

A concave portion 151 is formed on a side surface of the metal substrate 150 forming the guide hole 140. The concave portion 151 is provided in a shape recessed inward in the direction of the metal substrate 150.

The guide hole 140 comprises a first portion 141 formed by the upper anodized film 110, a second portion 142 formed by the metal substrate 150, and a third portion 143 formed by the lower anodized film 120.

The first portion 141 and the third portion 143 of the guide hole 140 are provided in a vertical shape, and the second portion 142 is provided in a shape recessed inward more than the first portion 141 and the third portion 143. As the second portion 142 is provided in a concave shape with respect to the first portion 141 and the third portion 143, the electrically conductive pin 10 does not contact the metal substrate 150, preventing the electrically conductive pin 10 from being electrically connected to the guide plate 100.

Aside anodized film 130 is formed on a side surface of the metal substrate 150 forming the guide hole 140. Through the configuration of the side anodized film 130, the surface of the metal substrate 150 is not exposed toward the guide hole 140. The side anodized film 130 is provided in the concave portion 151 of the metal substrate 150 conformally. Since the side anodized film 130 is a film formed by anodizing the metal substrate 150, the side anodized film 130 is integrally formed with the metal substrate 150, providing insulation to the inner wall surface of the guide hole 140. The metal substrate 150 is not exposed to the outside by the upper anodized film 110, the lower anodized film 120, and the side anodized film 130. This ensures insulation between the electrically conductive pin 10 and the guide plate 100.

The side anodized film 130 can be formed in a separate anodizing process from the process of forming the upper anodized film 110 and the lower anodized film 120. In other words, the upper anodized film 110 and the lower anodized film 120 are formed together in a first anodizing process, and the side anodized film 130 is formed in a second anodizing process separate from the first anodizing process. Therefore, the upper anodized film 110 and the lower anodized film 120 have the same thickness, but the side anodized film 130 can have a different thickness from the thickness of the upper anodized film 110 and the lower anodized film 120.

Referring to FIGS. 15 and 17, the upper guide hole 140a in which the head portion of the electrically conductive pin 10 is located has a structure in which the upper side opening area is smaller than the lower side opening area, and the lower guide hole 140b in which the tail portion of the electrically conductive pin 10 is located has a structure in which the upper side opening area is larger than the lower side opening area. In other words, the upper guide hole 140a of the upper guide plate 100a has an upper side opening area smaller than the lower side opening area, and the lower guide hole 140b of the lower guide plate 100b has an upper side opening area larger than the lower side opening area.

The upper guide hole 140a has a structure in which the upper side is narrower and the lower side is wider. This supports the electrically conductive pin 10 so that it does not shake and allows the electrically conductive pins 10 to be arranged in a narrow pitch. Additionally, the lower side of the upper guide hole 140a is relatively wide, making it easier for the electrically conductive pin 10 to elastically deform.

The lower guide hole 140b has a structure in which the upper side is wider and the lower side is narrower. This supports the electrically conductive pin 10 so that it does not shake and allows the electrically conductive pins 10 to be arranged in a narrow pitch. Additionally, the upper side of the lower guide hole 140b is relatively wide, making it easier for the electrically conductive pin 10 to elastically deform.

As a method of manufacturing the pin block 500 comprising the electrically conductive pins 10, (i) a method of inserting the electrically conductive pins 10 in a state where the upper guide plate 100a and the lower guide plate 100b are arranged as shown in FIG. 15 to complete the pin block 500 as shown in FIG. 17, or (ii) a method of inserting the electrically conductive pins 10 in a state where the upper guide hole 140a of the upper guide plate 100a and the lower guide hole 140b of the lower guide plate 100b are arranged in a vertical line and then shifting the upper guide plate 100a or the lower guide plate 100b to one side to complete the pin block 500 as shown in FIG. 17 can be used.

Hereinafter, a manufacturing method of the guide plate 100 according to a preferred second embodiment of the present invention will be described with reference to FIGS. 18 to 20.

First, referring to FIG. 18, the same process as described in the first embodiment with reference to FIGS. 5 to 8 is performed to provide an upper anodized film 110 on the upper portion of the metal substrate 150 and form a lower anodized film 120 on the lower portion of the metal substrate 150, and form a guide hole 140 penetrating the upper anodized film 110, the metal substrate 150, and the lower anodized film 120. At this time, the patternable material 270 shown in FIG. 8 may or may not be present. FIG. 18 shows a state in which the patternable material 270 is removed, unlike FIG. 8.

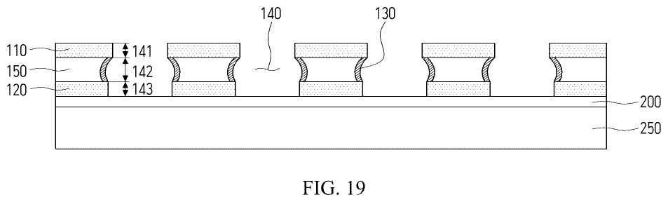

Next, referring to FIG. 19, the metal substrate 150 is anodized to form a side anodized film 130. The side anodized film 130 prevents the metal substrate 150 from being exposed to the guide hole 140. The side anodized film 130 is formed along the surface shape of the concave portion 151.

The upper anodized film 110 and the lower anodized film 120 are formed by the first anodizing process, and the side anodized film 130 is formed by the second anodizing process. Therefore, the thickness of the upper anodized film 110 and the lower anodized film 120 is the same, but the thickness of the upper anodized film 110 and the lower anodized film 120 may differ from the thickness of the side anodized film 130. Also, the upper anodized film 110 and the lower anodized film 120 have a structure in which the porous layer 20 and the barrier layer 30 are together (see FIG. 3), while the side anodized film 130 may have a structure in which only the barrier layer 30 is present. Alternatively, the upper anodized film 110 and the lower anodized film 120 may have a structure in which only the barrier layer 30 is present, while the side anodized film 130 may have a structure in which the porous layer 20 and the barrier layer 30 are together. Alternatively, the upper anodized film 110, the lower anodized film 120, and the side anodized film 130 may all have a structure in which the porous layer 20 and the barrier layer 30 are together, or a structure in which only the barrier layer 30 is present.

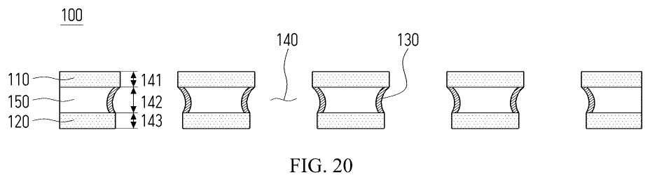

Next, referring to FIG. 20, by removing the patternable material 270, the adhesive layer 200, and the carrier substrate 250, the production of the guide plate 100 having the upper anodized film 110 and the lower anodized film 120 on both sides of the metal substrate 150 and the side anodized film 130 on the side of the metal substrate 150 is completed.

FIG. 21 is a view showing a first modification of the pin block 500 shown in FIG. 17. The first modification described below will be described focusing on characteristic components compared to the second embodiment described above, and descriptions of components that are the same as or similar to those of the second embodiment will be omitted as much as possible.

Referring to FIG. 21, the upper guide plate 110a includes a first upper guide plate 100aa having a first upper guide hole 140aa and a second upper guide plate 100ab having a second upper guide hole 140ab located below the first upper guide plate 100aa.

The lower guide plate 100b includes a first lower guide plate 100ba having a first lower guide hole 140ba and a second lower guide plate 100bb having a second lower guide hole 140bb located below the first lower guide plate 100ba.

The first upper guide plate 100aa and the second upper guide plate 100ab are fixed to each other by an upper fixing member 310 at a side portion in an upper and lower direction and are spaced apart from each other at a central portion in the upper and lower direction. The lower anodized film 120 of the first upper guide plate 100aa and the upper anodized film 110 of the second upper guide plate 100ab face each other.

The first lower guide plate 100ba and the second lower guide plate 100bb are fixed to each other by a lower fixing member 320 at a side portion in an upper and lower direction and are spaced apart from each other at a central portion in the upper and lower direction. The lower anodized film 120 of the first lower guide plate 100ba and the upper anodized film 110 of the second lower guide plate 100bb face each other.

The first upper guide hole 140aa of the first upper guide plate 100aa is arranged in a structure in which the upper side opening area is smaller than the lower side opening area. As a result, the upper part of the first upper guide hole 140aa is relatively narrow, supporting the electrically conductive pin 10 so that it does not shake and allowing the electrically conductive pin 10 to be arranged in a narrow pitch.

The second upper guide hole 140ab of the second upper guide plate 100ab is arranged in a structure in which the upper side opening area is larger than the lower side opening area. As a result, the tail portion of the electrically conductive pin 10 that has passed through the first upper guide hole 140aa is more easily guided and inserted into the second upper guide hole 140ab.

The first lower guide hole 140ba of the first lower guide plate 100ba is arranged in a structure in which the upper side opening area is larger than the lower side opening area. As a result, the tail portion of the electrically conductive pin 10 that has passed through the second upper guide hole 140ab is more easily guided and inserted into the first lower guide hole 140ba.

The second lower guide hole 140bb of the second lower guide plate 100bb is arranged in a structure in which the upper side opening area is larger than the lower side opening area. As a result, the tail portion of the electrically conductive pin 10 that has passed through the first lower guide hole 140ba is more easily guided and inserted into the second lower guide hole 140bb. Also, the lower part of the second lower guide hole 140bb is relatively narrow, supporting the electrically conductive pin 10 so that it does not shake and allowing the electrically conductive pin 10 to be arranged in a narrow pitch.

By arranging the first upper guide hole 140aa, the second upper guide hole 140ab, the first lower guide hole 140ba, and the second lower guide hole 140bb in the order of upper narrow lower wide, upper wide lower narrow, upper wide lower narrow, and upper wide lower narrow structures, it is possible to more easily insert and install the electrically conductive pin 10 and to firmly support the electrically conductive pin 10.

FIG. 22 is a view showing a second modification of the pin block 500 shown in FIG. 17. The second modification described below will be described focusing on characteristic components compared to the second embodiment described above, and descriptions of components that are the same as or similar to those of the second embodiment will be omitted as much as possible.

Referring to FIG. 22, the upper guide plate 100a includes a first upper guide plate 100aa having a first upper guide hole 140aa and a second upper guide plate 100ab having a second upper guide hole 140ab located below the first upper guide plate 100aa.

The lower guide plate 100b includes a first lower guide plate 100ba having a first lower guide hole 140ba and a second lower guide plate 100bb having a second lower guide hole 140bb located below the first lower guide plate 100ba.

The first upper guide plate 100aa and the second upper guide plate 100ab are bonded and stacked by a bonding layer in an upper and lower direction. The lower anodized film 120 of the first upper guide plate 100aa and the upper anodized film 110 of the second upper guide plate 100ab face each other.

The first lower guide plate 100ba and the second lower guide plate 100bb are bonded and stacked by a bonding layer in an upper and lower direction. The lower anodized film 120 of the first lower guide plate 100ba and the upper anodized film 110 of the second lower guide plate 100ba face each other.

Here, the material of the bonding layer 600 is not particularly limited, but may include a photoresist having adhesiveness.

The first upper guide hole 140aa of the first upper guide plate 100aa is arranged in a structure in which the upper side opening area is smaller than the lower side opening area. On the other hand, the second upper guide hole 140ab of the second upper guide plate 100ab is arranged in a structure in which the upper side opening area is larger than the lower side opening area. When the first upper guide plate 100aa and the second upper guide plate 100ab are bonded, they are symmetrical in the upper and lower directions based on the bonding layer 600. Of course, the first upper guide hole 140aa may be arranged in a structure in which the upper side opening area is larger than the lower side opening area, and the second upper guide hole 140ab may be arranged in a structure in which the upper side opening area is smaller than the lower side opening area.

The first lower guide hole 140ba of the first lower guide plate 100ba is arranged in a structure in which the upper side opening area is larger than the lower side opening area. On the other hand, the second lower guide hole 140bb of the second lower guide plate 100bb is arranged in a structure in which the upper side opening area is smaller than the lower side opening area. When the first lower guide plate 100ba and the second lower guide plate 100bb are bonded, they are symmetrical in the upper and lower directions based on the bonding layer 600. Of course, the first lower guide hole 140ba may be arranged in a structure in which the upper side opening area is smaller than the lower side opening area, and the second lower guide hole 140bb may be arranged in a structure in which the upper side opening area is larger than the lower side opening area.

### Third Embodiment

Next, a third embodiment according to the present invention will be described. The third embodiment described below will be described focusing on characteristic components compared to the first embodiment, and descriptions of components that are the same as or similar to those of the first embodiment will be omitted as much as possible.

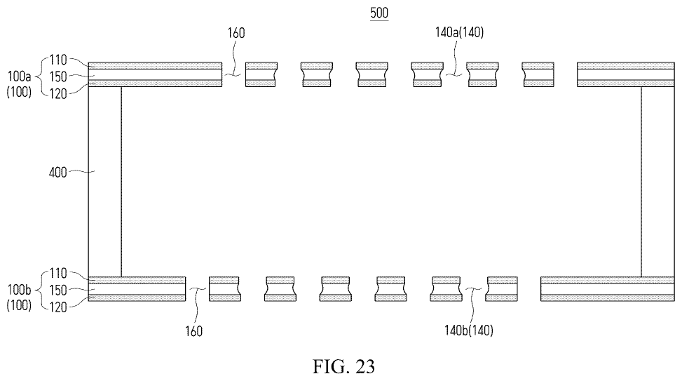

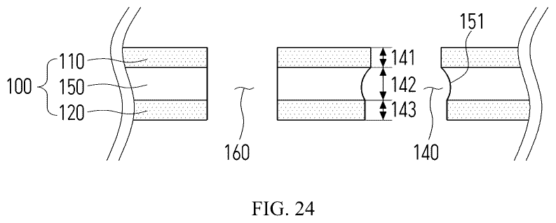

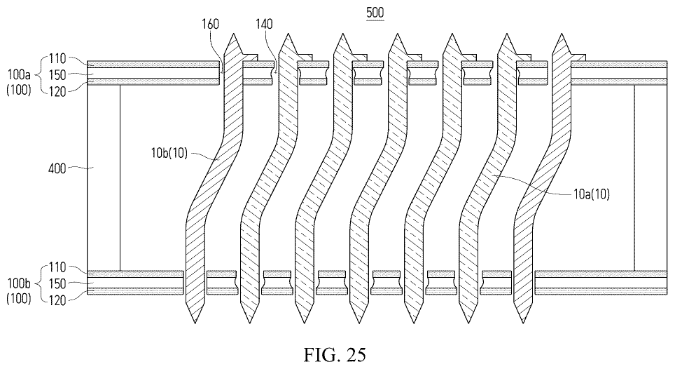

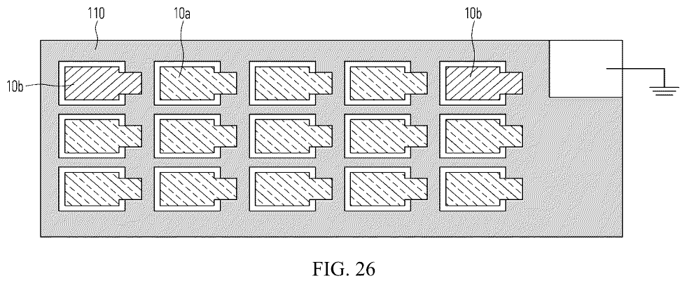

FIG. 23 is a view showing a pin block 500 without electrically conductive pins 10 according to a preferred third embodiment of the present invention, FIG. 24 is a view showing a guide plate 100 according to a preferred third embodiment of the present invention, FIG. 25 is a view showing a pin block 500 with electrically conductive pins 10 according to a preferred third embodiment of the present invention, and FIG. 26 is a plan view of the pin block 500 according to a preferred third embodiment of the present invention.

Referring to FIGS. 23 to 25, the pin block 500 comprises a guide plate 100 in which guide holes 140 into which electrically conductive pins 10 are inserted are formed. The guide plate 100 comprises an upper guide plate 100a in which upper guide holes 140a are formed and a lower guide plate 100b in which lower guide holes 140b are formed. A spacer 400 is provided between the upper guide plate 100a and the lower guide plate 100b.

At least one of the upper guide plate 100a and the lower guide plate 100b comprises a metal substrate 150, an upper anodized film 110 integrally formed with the metal substrate 150 and located on an upper portion of the metal substrate 150, and a lower anodized film 120 integrally formed with the metal substrate 150 and located on a lower portion of the metal substrate 150.

The upper anodized film 110 and the lower anodized film 120 are films formed by anodizing the metal substrate 150. When the metal substrate 150 is aluminum (Al) or an aluminum alloy, anodizing the metal substrate 150 forms an upper anodized film 110 and a lower anodized film 120 of aluminum oxide (Al₂O₃) material on both surfaces of the metal substrate 150. However, the metal substrate 150 is not limited to this and may comprise tantalum (Ta), niobium (Nb), titanium (Ti), zirconium (Zr), hafnium (Hf), tungsten (W), antimony (Sb), or alloys thereof.

The upper anodized film 110 and the lower anodized film 120 may have a structure comprising a porous layer 20 having pores P formed during anodizing and a barrier layer 30 located between the porous layer 20 and the metal substrate 150, or a structure comprising only the barrier layer 30.

The upper anodized film 110 and the lower anodized film 120 have a thermal expansion coefficient of 2˜3 ppm/° C. Therefore, when exposed to a high-temperature environment, thermal deformation due to temperature is minimal. Thus, even if the usage environment of the guide plate 100 is a high-temperature environment such as a burn-in test, it can be used without thermal deformation.

Since the guide plate 100 has a structure in which the upper anodized film 110 and the lower anodized film 120 are symmetrically provided on the upper and lower portions of the metal substrate 150, it is possible to prevent the guide plate 100 from bending in any one direction.

As the guide plate 100 comprises the metal substrate 150 inside, the fragility of the upper anodized film 110 and the lower anodized film 120 is compensated. Additionally, by utilizing the high heat capacity and thermal conductivity of the metal substrate 150, the guide plate 100 can easily perform heat dissipation and heat transfer to the outside in a high-temperature environment. Furthermore, the upper anodized film 110 and the lower anodized film 120 can resist the relatively large thermal expansion of the metal substrate 150 in a high-temperature environment, maintaining the positional accuracy of the electrically conductive pins 10 despite temperature changes. In particular, since the metal substrate 150 is not exposed to the outside by the upper anodized film 110 and the lower anodized film 120, the thermal expansion of the metal substrate 150 can be minimized even in a high-temperature environment.

The guide plate 100 comprises guide holes 140 and vertical guide holes 160.

The guide holes 140 may have the same configuration as the guide holes 140 described in the first embodiment or the same configuration as the guide holes 140 with side anodized films 130 described in the second embodiment.

With respect to one guide hole 140, the opening area formed in the upper anodized film 110 and the opening area formed in the lower anodized film 120 are different. Since the opening areas formed in the upper anodized film 110 and the lower anodized film 120 are different, one is larger or smaller than the other.

A concave portion 151 is formed on the side surface of the metal substrate 150 forming the guide hole 140. The concave portion 151 is provided in a shape recessed inward in the direction of the metal substrate 150.

The guide hole 140 comprises a first portion 141 formed by the upper anodized film 110, a second portion 142 formed by the metal substrate 150, and a third portion 143 formed by the lower anodized film 120.

The first portion 141 and the third portion 143 of the guide hole 140 are provided in a vertical shape, and the second portion 142 is provided in a shape recessed inward more than the first portion 141 and the third portion 143. As the second portion 142 is provided in a concave shape with respect to the first portion 141 and the third portion 143, the electrically conductive pin 10 does not contact the metal substrate 150, preventing the electrically conductive pin 10 from being electrically connected to the guide plate 100.

To further ensure the insulation between the electrically conductive pin 10 and the guide plate 100, it is possible to additionally provide a separate insulating coating layer (not shown) on the inner wall surface of the guide hole 140 or to additionally provide a side anodized film 130 as described in the second embodiment.

In the vertical guide hole 160, the opening area formed in the upper anodized film 110, the opening area formed in the metal substrate 150, and the opening area formed in the lower anodized film 120 are the same. The concave portion 151 is formed only in the guide hole 140 and not in the vertical guide hole 160.

The vertical guide hole 160 is manufactured by wet etching the upper anodized film 110 to form a hole with vertical sides, then dry etching the metal substrate 150 using the opening area of the upper anodized film 110 as a mask to form a hole with vertical sides in the metal substrate 150, and then wet etching the lower anodized film 120 using the opening area of the metal substrate 150 as a mask to form a hole with vertical sides. Therefore, unlike the guide hole 140, the vertical guide hole 160 is provided with vertical sides overall and the opening area is also formed to be the same overall.

The electrically conductive pin 10 inserted into the guide hole 140 does not contact the metal substrate 150 within the guide hole 140. On the other hand, the electrically conductive pin 10 inserted into the vertical guide hole 160 can contact the metal substrate 150 within the vertical guide hole 160.

The electrically conductive pin 10a inserted into the guide hole 140 and the electrically conductive pin 10b inserted into the vertical guide hole 160 may have different functions. The electrically conductive pin 10a inserted into the guide hole 140 may be a pin configured to transmit operation signals, i.e., input/output signals between the test equipment and the test object. On the other hand, the electrically conductive pin 10b inserted into the vertical guide hole 160 may be a pin configured to transmit ground signals or power signals.

The metal substrate 150 forms a common ground plane electrically connecting the vertical guide holes 160 by being embedded in the guide plate 100. Since the electrically conductive pins 10b transmitting ground signals are electrically connected through the metal substrate 150 of the vertical guide holes 160, it is possible to eliminate noise generated by different grounds.

Additionally, as the electrically conductive pins 10b configured to transmit ground signals are inserted into the vertical guide holes 160 and electrically connected to the metal substrate 150, it becomes possible to eliminate noise from the operation signals transmitted by the electrically conductive pins 10a inserted into the guide holes 140.

In the above description, the guide plate 100 according to a preferred embodiment of the present invention is used to support electrically conductive pins 10 in a test device. For example, the test device may be a test device used in a semiconductor manufacturing process or a display manufacturing process, and an example of a test device used in a semiconductor manufacturing process may be a probe card or a test socket. The guide plate 100 may be provided in a probe card and used to test semiconductor devices or provided in a test socket for testing packaged semiconductor packages. The test devices in which the guide plate 100 according to a preferred embodiment of the present invention can be used are not limited to this, and include all test devices for checking the defectiveness of a test object by applying electricity.

The inspection target of the inspection device may include semiconductor devices, memory chips, microprocessor chips, logic chips, light-emitting devices, or combinations thereof. For example, the inspection target may include logic LSI (such as ASIC, FPGA, and ASSP), microprocessors (such as CPU and GPU), memory (DRAM, HMC (Hybrid Memory Cube), MRAM (Magnetic RAM), PCM (Phase-Change Memory), ReRAM (Resistive RAM), FeRAM (Ferroelectric RAM), and flash memory (NAND flash)), semiconductor light-emitting devices (including LED, mini LED, micro LED, etc.), power devices, analog ICs (such as DC-AC converters and insulated gate bipolar transistors (IGBT)), MEMS (such as accelerometers, pressure sensors, vibrators, and gyro sensors), wireless devices (such as GPS, FM, NFC, RFEM, MMIC, and WLAN), discrete devices, BSI, CIS, camera modules, CMOS, passive devices, GAW filters, RF filters, RF IPD, APE, and BB.

As described above, although the preferred embodiments of the present invention have been described with reference to the accompanying drawings, those skilled in the art can make various modifications or changes to the present invention without departing from the spirit and scope of the invention as set forth in the following claims.

What is claimed is:

1. A guide plate in which guide holes into which electrically conductive pins are inserted are formed, comprising:
a metal substrate;
an upper anodized film integrally formed with the metal substrate and located on an upper portion of the metal substrate; and
a lower anodized film integrally formed with the metal substrate and located on a lower portion of the metal substrate.

2. The guide plate of claim 1, wherein
the upper anodized film and the lower anodized film are formed by anodizing the metal substrate.

3. The guide plate of claim 1, wherein
with respect to one guide hole, an opening area formed in the upper anodized film and an opening area formed in the lower anodized film are different.

4. The guide plate of claim 1, wherein
a concave portion is formed on a side surface of the metal substrate forming the guide hole.

5. The guide plate of claim 1, wherein
the guide hole comprises:
a first portion formed by the upper anodized film;
a second portion formed by the metal substrate; and
a third portion formed by the lower anodized film.

6. The guide plate of claim 5, wherein
the guide hole is configured such that the first portion and the third portion are provided in a vertical shape, and the second portion is provided in a shape recessed inward.

7. The guide plate of claim 6, further comprising
a vertical guide hole in which an opening area formed in the upper anodized film, an opening area formed in the metal substrate, and an opening area formed in the lower anodized film are the same.

8. The guide plate of claim 1, wherein
a side anodized film is formed on a side surface of the metal substrate forming the guide hole so that a surface of the metal substrate is not exposed toward the guide hole.

9. The guide plate of claim 1, wherein
a plurality of the guide plates are bonded and stacked by a bonding layer in an upper and lower direction.

10. The guide plate of claim 1, wherein
a plurality of the guide plates are fixed to each other by a fixing member at a side portion in an upper and lower direction and are spaced apart from each other at a central portion in the upper and lower direction.

11. A pin block comprising:
an upper guide plate in which upper guide holes into which electrically conductive pins are inserted are formed;
a lower guide plate in which lower guide holes into which the electrically conductive pins are inserted are formed; and
a spacer provided between the upper guide plate and the lower guide plate,
wherein at least one of the upper guide plate and the lower guide plate comprises:
a metal substrate;
an upper anodized film integrally formed with the metal substrate and located on an upper portion of the metal substrate; and
a lower anodized film integrally formed with the metal substrate and located on a lower portion of the metal substrate.

12. The pin block of claim 11, wherein
the upper guide hole in which a head portion of the electrically conductive pin is located has a structure in which an upper side opening area is smaller than a lower side opening area, and
the lower guide hole in which a tail portion of the electrically conductive pin is located has a structure in which an upper side opening area is larger than a lower side opening area.

13. The pin block of claim 11, wherein
the upper guide plate comprises a first upper guide plate and a second upper guide plate,
the first upper guide plate and the second upper guide plate are fixed to each other by an upper fixing member at a side portion in an upper and lower direction and are spaced apart from each other at a central portion in the upper and lower direction, and
a lower anodized film of the first upper guide plate and an upper anodized film of the second upper guide plate face each other.

14. The pin block of claim 11, wherein
the lower guide plate comprises a first lower guide plate and a second lower guide plate,
the first lower guide plate and the second lower guide plate are fixed to each other by a lower fixing member at a side portion in an upper and lower direction and are spaced apart from each other at a central portion in the upper and lower direction, and
a lower anodized film of the first lower guide plate and an upper anodized film of the second upper guide plate face each other.

15. The pin block of claim 11, wherein
the upper guide plate comprises a first upper guide plate and a second upper guide plate,
the first upper guide plate and the second upper guide plate are bonded and stacked by a bonding layer in an upper and lower direction, and
a first lower anodized film of the first upper guide plate and a second upper anodized film of the second upper guide plate face each other.

16. The pin block of claim 11, wherein
the lower guide plate comprises a first lower guide plate and a second lower guide plate,
the first lower guide plate and the second lower guide plate are bonded and stacked by a bonding layer in an upper and lower direction, and
a lower anodized film of the first lower guide plate and an upper anodized film of the second lower guide plate face each other.
